(19) United States
(12) Patent Application Publication
(10) Pub. No.: US 2020/0271486 A1
(43) Pub. Date: Aug. 27, 2020

(54) METHOD FOR PRODUCING AN ELECTRIC COMPONENT AND ELECTRIC COMPONENT

(71) Applicant: Vitesco Technologies Germany GMBH, Hannover (DE)

(72) Inventors: Alexander Taege, Erfurt (DE); Gerhard Hinkel, Hiltpoltstein (DE); Benjamin Lang, Nürnberg (DE)

(73) Assignee: Vitesco Technologies Germany GMBH, Hannover (DE)

(21) Appl. No.: 16/722,829

(22) Filed: May 18, 2020

Related U.S. Application Data
(63) Continuation of application No. PCT/EP2018/066014, filed on Jun. 15, 2018.

(30) Foreign Application Priority Data
Jun. 28, 2017 (DE) 10 2017 210 979.3

(51) Int. Cl. G01D 11/24; H05K 5/02; H05K 5/06; H01R 13/405; H01R 43/24; H05K 5/00; B29C 45/14

(52) U.S. Cl. CPC G01D 11/245; H05K 5/0247; H05K 5/065; H01R 13/405; B29K 2705/00; H05K 5/0082; B29C 45/14065; B29C 45/14549; B29C 45/1418; H01R 43/24

(57) ABSTRACT

A method for producing an electric component, including at least one component assembly, wherein the component assembly includes a mounting support and at least one electrically conductive metal wire. In order to form the component assembly the at least one electrically conductive metal wire is mounted on and/or in the mounting support, and the at least one component assembly is covered at least in sections with plastic, in particular is injection moulded at least in sections, in a plastic casting method, in particular in a plastic injection-moulding method. The invention further relates to an electric component.

### CROSS-REFERENCE TO RELATED APPLICATIONS

This application claims priority to PCT Application PCT/EP2018/066014, filed Jun. 15, 2018, which claims priority to German Application DE 10 2017 210 979.3, filed Jun. 28, 2017. The disclosures of the above applications are incorporated herein by reference.

### FIELD OF THE INVENTION

The invention concerns a method for producing an electric component and an electric component.

### BACKGROUND

Electric components configured as sensor domes are generally known from the prior art. Such sensor domes are used for example in gear mechanism control units, and comprise a sensor which is arranged spaced apart from a circuit board of the gear mechanism control unit in order for example to be able to be positioned lying on a gear casing or protruding into the gear casing. The sensor is connected to the circuit board by means of electrical connecting lines formed by a stamped grid. For electrical insulation and protection, at least the electrical connecting lines are over-molded with plastic so as to form the sensor dome, i.e. the sensor with its electrical connecting lines, formed from the stamped grid and over-molded with plastic, forms the sensor dome.

This sensor dome is produced in that a stamped grid is formed by punching and bending using a punching and bending follow-on tool, and is then galvanized and deburred. The stamped grid is then pre-overmolded with plastic, i.e. in a first plastic injection molding process it is partly over-molded with plastic, and holding webs are punched out. It is then fitted with the sensor and the final over-molding with plastic takes place, i.e. a further plastic injection molding process, in which a plastic casing is formed on the sensor dome. Then a swarf protection cap is placed on the sensor. The sensor dome produced in this way may be arranged on a circuit board, wherein for electrical contacting with the circuit board, the free ends of the electrical lines formed by means of the stamped grid are connected to the circuit board and for example soldered.

### SUMMARY

The invention is based on the object of specifying a method for production of an electric component which is improved in comparison with the prior art, and an electric component which is improved in comparison with the prior art.

The object is achieved according to the invention with a method for production of an electric component with the features described herein, and an electric component with the features also described.

Advantageous refinements of the invention are also described herein.

In a method according to the invention for producing an electric component, an electric component is produced which comprises at least one component assembly, wherein the component assembly comprises a mounting support and at least one electrically conductive metal wire. Advantageously, the component assembly comprises several such metal wires, for example two metal wires. Firstly, the at least one component assembly is formed in that at least the at least one electrically conductive metal wire, or the several electrically conductive metal wires, is/are arranged on and/or in the mounting support. Formation of the at least one component assembly may also comprise further steps, in particular the arrangement of further components, as will be explained in more detail below with reference to further embodiments. The at least one component assembly thus formed is then covered at least in regions with a plastic, in particular coated at least in regions, in a plastic molding process. Advantageously, it is over-molded at least in regions in a plastic molding process configured as a plastic injection molding process.

The method according to the invention is particularly suitable for production of a sensor dome or another sensor assembly, in particular for sealed housing of one or more sensors, or for producing a plug or another electrical contacting assembly or other suitable electrical contact system.

As already stated, such sensor domes were previously produced by forming a stamped grid by punching and bending using a punching and bending follow-on tool, and then galvanized and deburred. The stamped grid is then pre-over-molded with plastic, i.e. in a first plastic injection molding process it is partly over-molded with plastic, and holding webs are punched out. It is then fitted with the sensor and the final over-molding with plastic takes place, i.e. a further plastic injection molding process, in which a plastic casing is formed on the sensor dome. Then a swarf protection cap is placed on the sensor. Due to the double over-molding with plastic, although the stamped grid is well sealed, this former procedure still has substantial disadvantages. The necessary punching and bending follow-on tool is very expensive, for example costing over €200,000, and only has a limited service life. Furthermore, said pre-overmolding is necessary, i.e. the first plastic injection molding process for partial over-molding of the stamped grid, for which it is necessary to lay the stamped grid in an injection molding tool. Punching out the holding webs is an additional process step with costly tools. This entails the risk of contamination, the risk of burr formation, the risk of defective punching out and the resulting short circuit or insufficient spacing between electrical lines, and the risk of bending the stamped grid. This method previously applied thus entails high tooling costs but has comparatively low unit costs, and is therefore suitable for a high production volume of for example over 100,000 sensor domes per year.

By means of the method according to the invention, said disadvantages are avoided. In particular, there is no need for costly punching and bending follow-on tools for the method according to the invention. Shorter tooling times apply since many process steps are omitted. In particular, there is no need to form, galvanize, deburr, pre-overmold and punch out the stamped grid, whereby tooling costs and process risks are avoided. For example, a simple economic pre-galvanized wire material on a roll may be used as the metal wire. Furthermore, by means of the method according to the invention, greater complexity is possible since for example the metal wires may be arranged in several layers, and several mounting supports and/or electrical function elements to be described in more detail below, for example sensors, may be used, and/or different metal wires may be used, for example in different thicknesses, different materials and different galvanizing states. A particular advantage of the method according to the invention is that the component assembly formed can already be tested for its function suitability, i.e. before being covered with plastic at least in regions. In this way for example, improvements or repairs are possible, for example even a component replacement, in order to ensure function suitability. The production of faulty electric components, which can no longer be repaired because of the final plastic covering, is thus avoided or at least substantially reduced.

The method according to the invention indeed requires a greater mounting complexity, giving a risk of mounting faults, but these mounting faults may be avoided for example by so-called poka-yoke design elements which mean that it is not possible to mount incorrectly oriented components, and by test steps. Higher unit costs result from the greater mounting complexity, so the method according to the invention is suitable in particular for small quantities, i.e. for a smaller production volume of for example less than 100,000 electric components, for example sensor domes, per year. In particular, the method according to the invention allows a shorter development times.

Advantageously, before arrangement on and/or in the mounting support, the at least one metal wire or the plurality of such metal wires is bent into a predefined form and/or is bent by the mounting support into a form predefined by the mounting support by being arranged on and/or in the mounting support. In the case of bending before arrangement on and/or in the mounting support, standard wire bending machines may be used, i.e. no costly special machines are required and the tooling costs are correspondingly low. In the case of bending by being arranged on and/or in the mounting support, the mounting support serves as a bending aid, so again no additional molds or tools are required, but bending may for example take place manually.

In an advantageous embodiment, to form the component assembly, at least one electrical function element, in particular a sensor, is arranged on and/or in the mounting support and connected in electrically conductive fashion, in particular welded, to the at least one metal wire or to the plurality of such metal wires. In other words, in this embodiment the component assembly also comprises the at least one electrical function element, in particular the sensor. If the electrical function element is configured as a sensor, for example a sensor dome is formed as an electric component. Welding takes place for example by resistance welding. With a corresponding design of the mounting support, a two-sided access to the respective electrical connecting contact of the electrical function element, which is to be connected to the respective metal wire, can be ensured so that connection can easily be achieved by resistance welding.

In an advantageous embodiment, to form the component assembly, in particular after arrangement and electrically conductive connection of the at least one electrical function element, at least one sealing and/or holding element is arranged on and/or in the mounting support. In other words, in this embodiment the component assembly also comprises the at least one sealing and/or holding element. This sealing and/or holding element in particular seals a region or space, in which the electrical function element, for example the sensor, is arranged, against penetrating plastic and stabilizes the respective metal wire on the connecting point to the electrical function element, which is formed for example as a welding seam. The sealing and/or holding element is therefore suitably positioned accordingly, i.e. in this connecting point region of the metal wire and electrical function element, more precisely their respective electrical connecting contacts.

In an advantageous embodiment, to form the component assembly, a protective cap is arranged on the mounting support, at least partially covering the least one electrical function element, and/or is arranged on the at least one electrical function element arranged in and/or on the mounting support. In other words, in this embodiment the component assembly also comprises the protective cap. In the case of a sensor dome provided for a gear mechanism control unit, this protective cap is for example configured as a swarf protection cap. The protective cap protects the electrical function element, for example the sensor, for example from contamination, e.g. oil and swarf from a gear mechanism in and/or on which the sensor dome is arranged. With the method according to the invention, in particular it is possible also to cover the protective cap at least partially with the plastic and hence seal this, so that for example an oil-tight protective cap can be produced.

Advantageously, for arrangement of the respective metal wire, the mounting support has a respective groove. The respective metal wire is then suitably laid in the respective groove and for example clipped, latched and/or bonded. The groove protects the respective metal wire in particular from so-called drifting during subsequent covering with plastic, for example during over-molding with plastic, i.e. against a position change which could for example lead to a contact with another metal wire and hence a short circuit.

When the electrical function element, for example the sensor, is arranged in position, it is advantageously laid in the mounting support and clipped and/or latched therein, i.e. held by a corresponding contour, in particular of the mounting support.

When the protective cap is arranged in position, this is advantageously pushed by form fit over the electrical function element and the sealing and/or holding element, and for example clipped and/or latched on the mounting support, i.e. held by a corresponding contour, in particular of the mounting support. Thus the protective cap supports the electrical function element, for example the sensor, and holds it in position.

The mounting support thus advantageously has corresponding contours, in particular holding contours, in order to hold all components arranged therein in their positions during the final covering with plastic.

The protective cap advantageously has one or more undercuts around which plastic is cast, in particular over-molded, so that the protective cap is held in its position on the finished electric component by the plastic.

As already stated, incorrect mounting may be excluded by corresponding design of the components. For example, the design is such that the protective cap cannot be pushed on and clipped and/or latched in the final position unless all components are in their respective correct positions.

Advantageously, the mounting support and/or the sealing and/or holding element, and/or the protective cap, is/are each formed from plastic before the component assembly is formed, in particular in a plastic molding process, preferably in a plastic injection molding process. Thus the production is simple to implement at low cost. In particular, the mounting support may be formed as a simple monolithic plastic component. In particular, no inlaying process is required for this. In other words, to produce the mounting support, there is no need to lay a part to be over-molded with plastic in a plastic injection molding tool, since no inlaying and over-molding of a stamped grid is required.

In an advantageous embodiment, a plurality of component assemblies is covered jointly with the plastic at least in regions, in particular coated at least in regions, in the plastic molding process. Advantageously, the plurality of component assemblies is over-molded jointly with the plastic, at least in regions, in a plastic molding process formed as a plastic injection molding process. As already stated, this allows for example a greater complexity of the electric component, which then has several supports with for example several electrical function elements, and for example is configured as a sensor dome with several sensors.

As an electric component, for example a sensor arrangement is produced, in particular a sensor dome, or an electrical contacting arrangement, in particular a plug. The method according to the invention thus offers the advantages already outlined in relation to the production of these electric components.

In a further embodiment, the protective cap is covered with the plastic at least in regions, in particular over-molded at least in regions, in the plastic molding process, in particular in the plastic injection molding process.

An electric component according to the invention, in particular produced by means of the method described above, comprises at least one component assembly, wherein the component assembly comprises a mounting support and at least one electrically conductive metal wire which is arranged on and/or in the mounting support. Advantageously, the component assembly comprises several such metal wires, for example two metal wires. The at least one component assembly is covered with a plastic at least in regions, in particular coated at least in regions, in particular is over-molded with the plastic at least in regions in a plastic injection molding process. This results in the advantages already outlined above in relation to the method for production of the electric component, which result in particular from its production and thus apply also to the electric component produced.

In an advantageous embodiment, to form the electric component, in particular its at least one electric component assembly, at least one electrical function element is arranged on and/or in the mounting support and connected in electrically conductive fashion, in particular welded, to the at least one metal wire or to the plurality of such metal wires. The at least one electrical function element is for example configured as a sensor. This results in the advantages already outlined above in relation to the method for production of the electric component, which result in particular from its production and thus apply also to the electric component produced.

In an advantageous embodiment, the electric component, in particular its at least one component assembly, comprises at least one sealing and/or holding element. This results in the advantages already outlined above in relation to the method for production of the electric component, which result in particular from its production and thus apply also to the electric component produced.

In an advantageous embodiment, the electric component, in particular its at least one component assembly, comprises a protective cap covering the at least one electrical function element at least in regions. This results in the advantages already outlined above in relation to the method for production of the electric component, which result in particular from its production and thus apply also to the electric component produced.

Advantageously, the mounting support and/or the sealing and/or holding element, and/or the protective cap, is/are each formed from plastic, in particular in a plastic molding process, preferably in a plastic injection molding process. This results in the advantages already outlined above in relation to the method for production of the electric component, which result in particular from its production and thus apply also to the electric component produced.

In an advantageous embodiment, the electric component comprises a plurality of component assemblies which are jointly covered with the plastic at least in regions, in particular coated at least in regions, in particular jointly over-molded with the plastic at least in regions in a plastic injection molding process. This results in the advantages already outlined above in relation to the method for production of the electric component, which result in particular from its production and thus apply also to the electric component produced.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

Exemplary embodiments of the invention are explained in more detail below with reference to drawings.

FIG. 1 diagrammatically, a perspective illustration of a stamped grid for a sensor dome according to the prior art;

FIG. 2 diagrammatically, a perspective illustration of a stamped grid for a sensor dome according to the prior art, which is over-molded with plastic at least in regions in a first plastic injection molding process;

FIG. 3 diagrammatically, a perspective illustration of a sensor dome according to the prior art with protective cap removed;

FIG. 4 diagrammatically, a perspective illustration of a sensor dome according to the prior art;

FIG. 5 diagrammatically, a perspective illustration of pre-bent metal wires for an electric component;

FIG. 6 diagrammatically, a perspective illustration of a mounting support, an electrical function element, a sealing and/or holding element, and a protective cap for an electric component;

FIG. 7 diagrammatically, an exploded view of an electric component;

FIG. 8 diagrammatically, a perspective illustration of a mounting support with metal wires arranged therein and an electrical function element connected to the metal wires and arranged in the mounting support for an electric component;

FIG. 9 diagrammatically, a perspective illustration of a mounting support with metal wires arranged therein, an electrical function element connected to the metal wires and arranged in the mounting support, a sealing and/or holding element arranged in the mounting support, and a protective cap for an electric component;

FIG. 10 diagrammatically, a perspective illustration of a component assembly for an electric component, comprising a mounting support with metal wires arranged therein, an electrical function element connected to the metal wires and arranged in the mounting support, a sealing and/or holding element arranged in the mounting support, and an applied protective cap;

FIG. 11 diagrammatically, a perspective illustration of an electric component;

FIG. 12 diagrammatically, a perspective illustration of an electric component in the region of an electrical function element;

FIG. 13 diagrammatically, a perspective illustration of several mounting supports and assigned metal wires for an electric component;

FIG. 14 diagrammatically, a further perspective illustration of several mounting supports and assigned metal wires for an electric component;

FIG. 15 diagrammatically, a perspective illustration of several mounting supports with metal wires arranged therein and each with an electrical function element connected to the respective metal wires and arranged in the respective mounting support for an electric component, and assigned protective caps;

FIG. 16 diagrammatically, a perspective illustration of several mounting supports attached to each other with metal wires arranged therein and each with an electrical function element connected to the respective metal wires and arranged in the respective mounting support for an electric component;

FIG. 17 diagrammatically, a perspective illustration of a component assembly for an electric component, comprising several mounting supports each with metal wires arranged therein, each with an electrical function element connected to the respective metal wires and arranged in the respective mounting support, and each with an applied protective cap; and

FIG. 18 diagrammatically, a perspective illustration of an electric component.

### DETAILED DESCRIPTION OF THE PREFERRED EMBODIMENTS

The following description of the preferred embodiment(s) is merely exemplary in nature and is in no way intended to limit the invention, its application, or uses.

In all of the figures, the same reference signs are used for mutually corresponding parts.

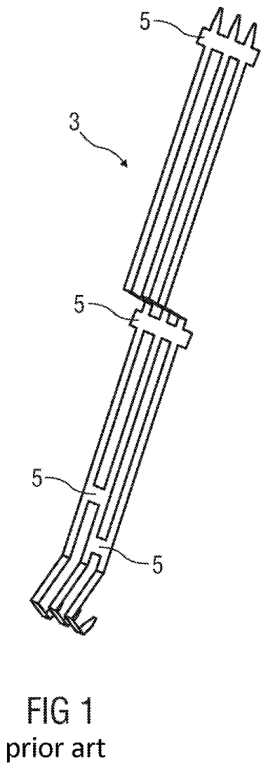

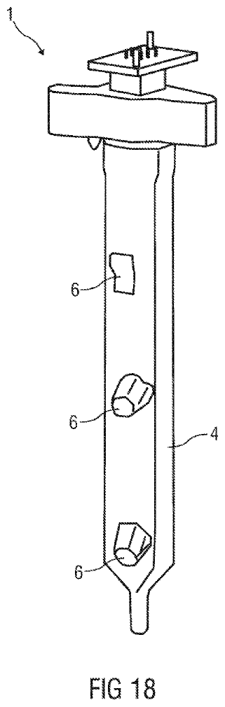

With reference to FIGS. 1 to 18, a production of an electric component 1 is described below using the example of a sensor dome. The electric component 1 is therefore referred to below as a sensor dome 1.

Such sensor domes 1 are used for example in gear mechanism control units (not shown here) and comprise a sensor as an electrical function element 2, for which reason the electrical function element 2 is referred to below as a sensor 2. The sensor 2 is arranged spaced apart from a circuit board of the gear mechanism control unit, in order thereby for example to be able to be positioned lying on a gear casing of a gear mechanism (not shown here) or protruding into the gear casing.

The sensor 2 is connected to the circuit board by means of electrical connecting lines. For electrical insulation and protection, at least the electrical connecting lines are over-molded with plastic 4.

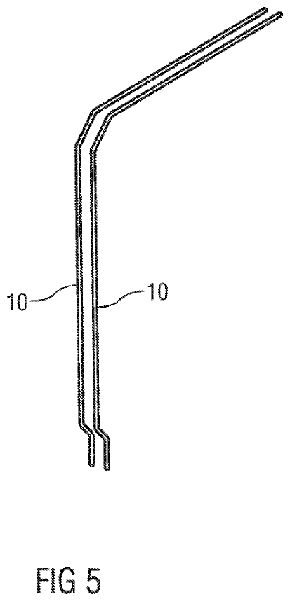

In particular by means of the method described below with reference to FIGS. 5 to 18, further electric components 1 may also be produced, for example other sensor arrangements or electric contacting assemblies, in particular plugs or other contact systems which in particular need not have an electrical function element 2.

With reference to FIGS. 1 to 4, firstly the production of the sensor dome 1 using a method known from the prior art is described. Here, a stamped grid 3 shown in FIG. 1, which serves to form the electrical connecting lines, is formed by punching and bending using a punching and bending follow-on tool, and then galvanized and deburred.

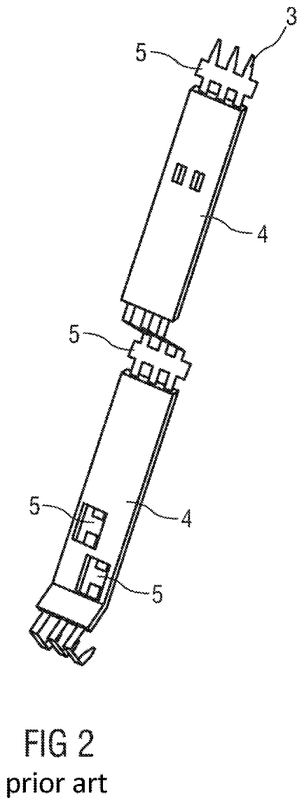

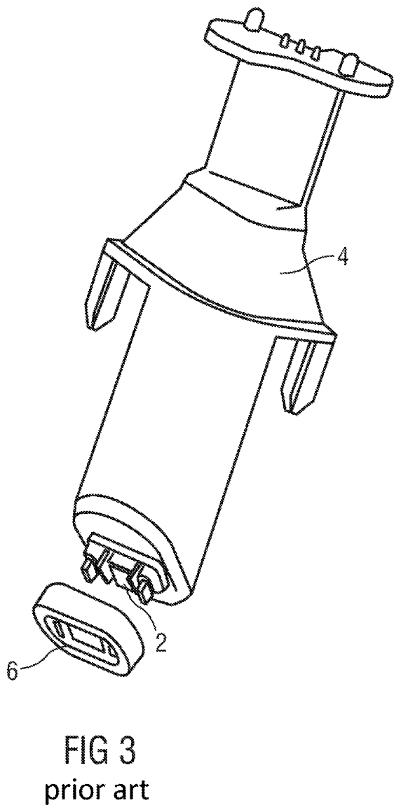

Then the stamped grid 3 is pre-overmolded with plastic 4, i.e. in a first plastic injection molding process is partly over-molded with plastic 4, as shown in FIG. 2, and holding webs 5 are punched out in order to separate the connections between the electrical connecting lines. It is then fitted with the sensor 2 and the final over-molding with plastic 4 takes place, i.e. a further plastic injection molding process in which a plastic casing is formed on the sensor dome 1, as shown in FIG. 3.

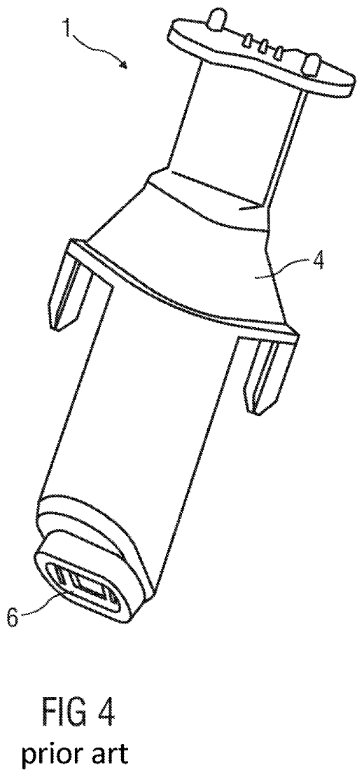

Then a protective cap 6 is applied to the sensor 2 as protection from swarf, also known as a swarf protection cap or swarf protection cover, as shown in FIG. 4. The sensor dome 1 produced in this way and shown in FIG. 4 may be arranged on a circuit board, for example of a gear mechanism control unit, wherein for electrical contacting to the circuit board, the free ends of the electrical connecting lines formed by means of the stamped grid 3 are connected to the circuit board and for example soldered. In the state when the gear mechanism control unit is mounted on the gear mechanism, the sensor dome 1, for example with its region in which the sensor 2 is arranged, then protrudes into the gear casing.

The punching and bending follow-on tools required for this process known from the prior art are very costly and only have limited service lives, so that this method entails high tooling costs. Furthermore, the pre-overmolding of the stamped grid 3 described is required, for which the stamped grid 3 must be inlaid in a plastic injection molding tool. The necessary punching out requires an additional process step with costly tools. This punching out entails the risk of contamination, the risk of burr formation, the risk of defective punching out and a resulting short circuit or insufficient spacing between electrical lines, and the risk of bending the stamped grid 3.

FIGS. 5 to 12, and 13 to 18 show two exemplary embodiments of a method according to the invention for producing an electric component 1, here configured as a sensor dome 1, which avoid the disadvantages of the process known from the prior art. The sensor dome 1 produced by means of this method may be used in the same way as already described above, i.e. it may be arranged on a circuit board, for example of the gear mechanism control unit, wherein for electrical contacting with the circuit board, electric contact elements of the sensor dome 1 are connected to the circuit board and for example soldered. In the state when the gear mechanism control unit is mounted on the gear mechanism, the sensor dome 1, for example with its region in which the sensor 2 is arranged, then protrudes into the gear casing.

As already stated, by means of this method, further electric components 1 may also be produced, for example other sensor arrangements or electric contacting assemblies, in particular plugs or other contact systems which in particular need not have an electrical function element 2.

In the exemplary embodiment shown in FIGS. 5 to 12, the electric component 1 configured as a sensor dome 1 comprises a component assembly 8 with mounting support 9, two electrically conductive metal wires 10 forming the electrical connecting lines, an electrical function element 2 configured as a sensor 2, a sealing and/or holding element 7, and a protective cap 6 known as a swarf protection cap.

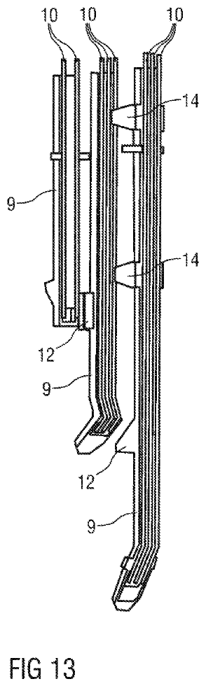

In the exemplary embodiment according to FIGS. 13 to 18, the electric component 1 formed as a sensor dome 1 comprises three such component assemblies 8 attached to each other, wherein here no sealing and/or holding elements 7 are provided, and wherein here two of the three component assemblies 8 have three metal wires 10, and the other component assembly 8 has two metal wires 10. In other exemplary embodiments, more or fewer such component assemblies 8 may be provided, i.e. one or more component assemblies 8, wherein for each component assembly 8, a respective sealing and/or holding element 7 may be provided or not, and one or more metal wires 10 may be provided.

In the exemplary embodiment in FIGS. 5 to 12, the electric component 1 configured as a sensor dome 1 is produced using the method for production in which the metal wires 10 are bent into a predefined form, i.e. pre-bent, as shown in FIG. 5. For this, advantageously pre-galvanized metal wires 10 from a roll are used and pre-bent using a standard wire bending machine.

Furthermore, the mounting support 9, the sealing and/or holding element 7, and the protective cap 6 are molded in a plastic injection molding process, i.e. made of plastic 4. For this, the same plastic 4 may be used or different plastics 4 may be used.

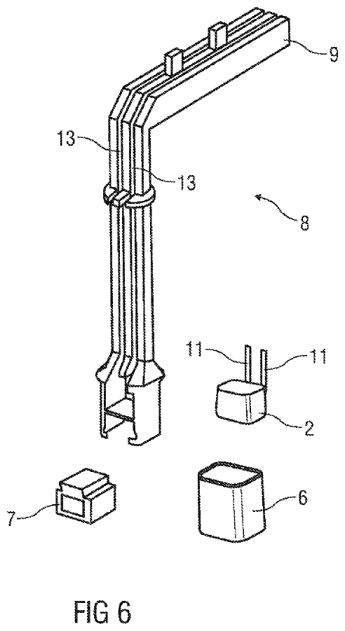

FIG. 6 shows, as well as the metal wires 10, all components necessary to form the component assembly 8 for this embodiment of the sensor dome 1, namely the mounting support 9, the electrical function element 2 configured as a sensor 2, the sealing and/or holding element 7, and the protective cap 6.

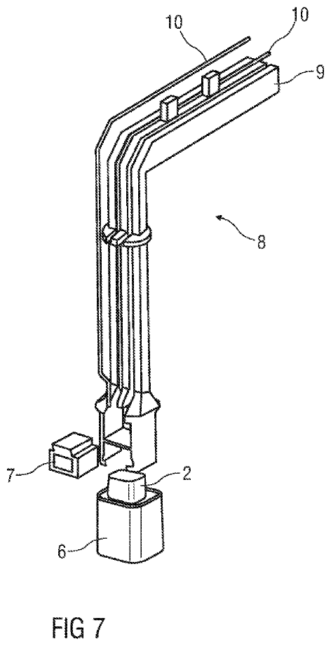

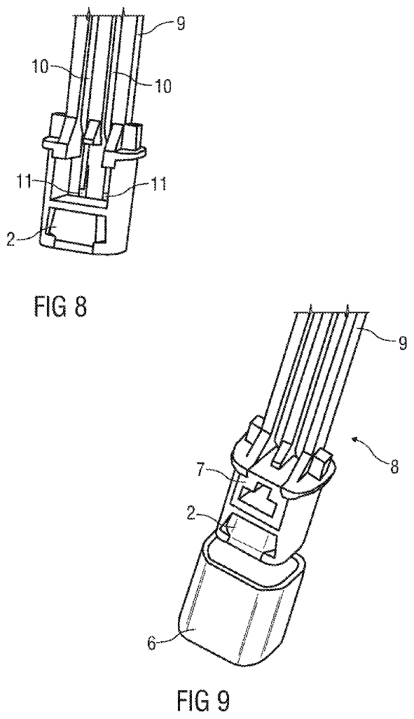

The mounting, i.e. formation of the component assembly 8, is illustrated in FIGS. 7 to 10. The metal wires 10 are laid in the mounting support 9, preferably arranged in grooves 13 formed therein. Then, as shown in FIG. 8, the sensor 2 is arranged in the mounting support 9 and connected to the metal wires 10, preferably by resistance welding. More precisely, electrical connecting contacts 11 of the sensor 2 are connected to the metal wires 10.

Then the sealing and/or holding element 7 is arranged in the mounting support 9, as shown in FIG. 9. This sealing and/or holding element 7 in particular seals a region or space, in which the electrical function element 2 (here configured as a sensor 2) is arranged, against penetrating plastic 4 and stabilizes the metal wires 10 at the connecting point to the connecting contacts 11, which is formed for example as a weld seam. The sealing and/or holding element 7 is therefore positioned accordingly, i.e. arranged in this connecting point region of the metal wires 10 and the electrical connecting contacts 11 of the electrical function element 2 configured as a sensor 2.

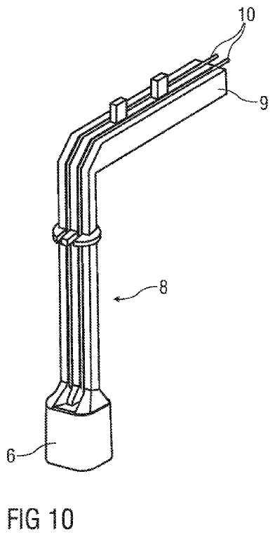

Then the protective cap 6 is mounted, i.e. pushed over the sensor 2 and sealing and/or holding element 7, as shown in FIG. 10. The component assembly 8 thus formed may already be tested for function suitability, so that if faults are detected, repairs or a component replacement can easily be performed.

To complete the electric component 1 formed as a sensor dome 1, the component assembly 8 is laid in a plastic injection molding tool and over-molded with a plastic 4 at least in regions. The plastic 4 may be the same plastic 4 which is also used to form the protective cap 6, the sealing and/or holding element 7, and/or the mounting support 9, or a different plastic 4.

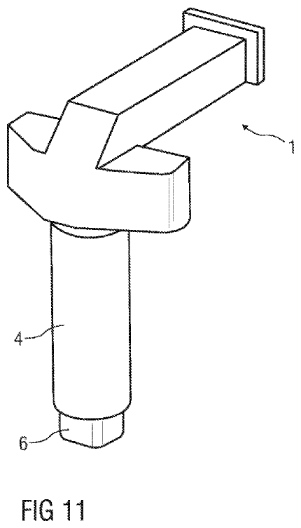

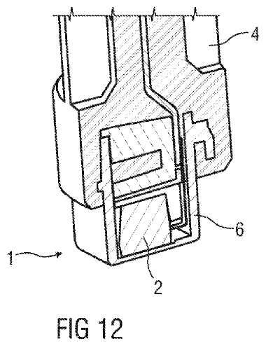

The completed electric component 1 formed as a sensor dome 1 is shown in FIGS. 11 and 12, wherein FIG. 12 shows the region in which the sensor 2 is arranged. Here and from FIG. 11, it is evident that the component assembly 8 is almost completely over-molded with the plastic 4. Only a partial region of the protective cap 6 and, where suitable, contact elements of the sensor dome 1 on the end of the sensor dome 1 facing away from the sensor 2, remain exposed. The respective contact element is formed by an end region of the respective metal wire 10 facing away from the sensor 2 and protruding out of the plastic 4.

As already stated, the further embodiment of the sensor dome 1, described in FIGS. 13 to 18, comprises three component assemblies 8 each of which substantially comprise the same components and are formed in the same fashion as in the first embodiment, described with reference to FIGS. 5 to 12. Only two of the three component assemblies 8 have three metal wires 10, and there are no sealing and/or holding elements 7.

The function of the sealing and/or holding element 7 in this embodiment may be performed fully or partially by a respective other mounting support 9 on which the respective component assembly 8 lies. The middle mounting support 9 has a protrusion 12 on which, after joining of the component assemblies 8, the sensor 2 of the front component assembly 8 lies so that this sensor 2 is supported and held by the protrusion 12 of the middle mounting support 9, and also at least partially covered, whereby the penetration of plastic 4 to the sensor 2 of the front component assembly 8 is avoided. Also, the mounting support 9 of the rear component assembly 8 has a protrusion 12 on which, after joining of the component assemblies 8, the sensor 2 of the middle component assembly 8 lies so that this sensor 2 is supported and held by the protrusion 12 of the rear mounting support 9, and also at least partially covered, whereby the penetration of plastic 4 to the sensor 2 of the middle component assembly 8 is avoided.

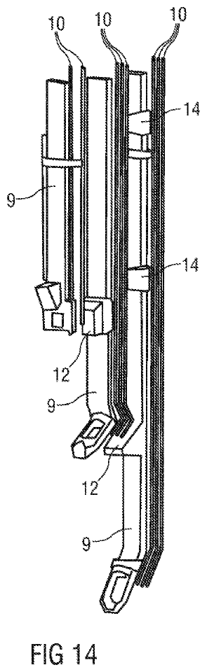

As already stated, mounting i.e. formation of the component assembly 8, takes place in a similar fashion to that already explained with reference to FIGS. 7 to 10. FIGS. 13 and 14 show, from two different perspectives, the mounting supports 9 and metal wires 10 of the respective component assemblies 8 in the state not yet joined together.

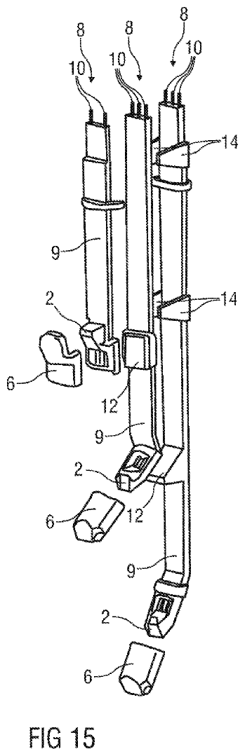

The metal wires 10 of the respective component assembly 8 are laid in the mounting support 9 of the respective component assembly 8, preferably arranged in grooves 13 formed therein. Then the electrical function element 2, formed as a sensor 2, of the respective component assembly 8 is arranged in the mounting support 9 of the respective component assembly 8 and connected to the metal wires 10, preferably by resistance welding. More precisely, electrical connecting contacts 11 of the sensor 2 are connected to the metal wires 10. This is shown in FIG. 15, wherein here already the protective caps 6 are shown which will be arranged covering the sensors 2 at a later time.

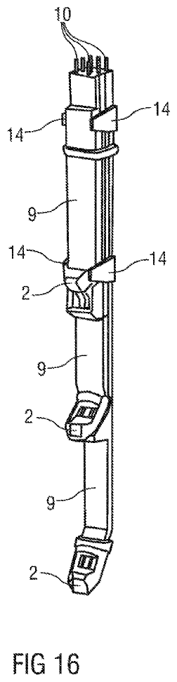

Now the three component assemblies 8, each comprising a mounting support 9, a sensor 2 arranged in the mounting support 9, and two or three electrically conductive metal wires 10 arranged in the mounting support 9 and attached to the sensor 2, are arranged and preferably attached to each other as shown in FIG. 16. In the embodiment shown here, the rear mounting support 9 has corresponding fixing elements 14 which are here formed as latching tabs.

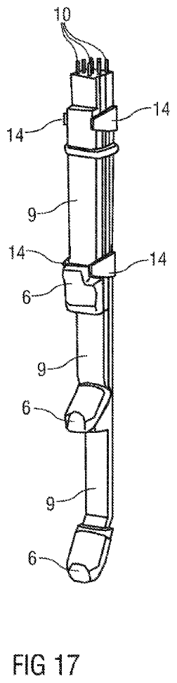

By arranging the middle mounting support 9 on the rear mounting support 9, and the front mounting support 9 on the middle mounting support 9, these fixing elements 14 formed as latching tabs on the rear mounting support 9 engage in the middle and front mounting supports 9, so that the three mounting supports 9 and hence the three component assemblies 8 are connected together. Then the three component assemblies 8 are completed by mounting the respective protective cap 6, as shown in FIG. 17. The respective protective cap 6 is pushed over the respective sensor 2.

The component assembly 8 thus formed may already be tested for function suitability before or after connection of the mounting supports 9, so that if faults are detected, repairs or a component replacement can easily be performed.

To complete the electric component 1, formed as a sensor dome 1, the component assemblies 8 connected together are jointly laid in a plastic injection molding tool and over-molded with a plastic 4 at least in regions. The completed electric component 1 formed as a sensor dome 1 is shown in FIG. 16. It is clear that the component assemblies 8 together are almost completely over-molded with the plastic 4. Only a partial region of the protective caps 6 and suitably the end regions of the metal wires 10 facing away from the sensors 2 and forming the contact elements of the sensor dome 1, remain exposed.

In the embodiments of the method according to the invention, the respective mounting supports 9 each advantageously have a respective groove 13 for arrangement of the respective metal wire 10. The metal wires 10 are then suitably laid in the respective groove 13 and for example clipped, latched and/or bonded. The groove 13 protects the respective metal wire 10 in particular from so-called drifting during subsequent covering with plastic 4, for example in the plastic injection moulding process, i.e. against a position change which could for example lead to a contact with another metal wire 10 and hence a short circuit.

The respective electrical function element 2 formed as a sensor 2 is advantageously laid in the respective mounting support 9 and clipped and/or latched therein, i.e. held by a corresponding contour, in particular of the mounting support 9.

By corresponding formation of the mounting support 9, a two-sided access can be ensured to the electrical connecting contacts 11 of the respective electrical function element 2 formed as sensor 2, which are to be connected to the respective metal wires 10, so that the connection can easily be achieved by resistance welding as shown in FIGS. 6 to 8, and 13 to 15.

The respective protective cap 6 is advantageously pushed by form fit over the respective electrical function element 2, here formed as a sensor 2, and pushed at least in regions over the sealing and/or holding element 7 where fitted, and for example clipped and/or latched to the mounting support 9, i.e. held by a corresponding contour, in particular of the mounting support 9. Thus the protective cap 6 supports the electrical function element 2, for example the sensor 2, and holds it in position.

The respective mounting support 9 thus advantageously has corresponding contours, in particular holding contours, in order to hold all components arranged therein in their positions during the final covering with plastic 4, in particular during the plastic over-molding.

The respective protective cap 6 advantageously has one or more undercuts which are over-molded with the plastic 4, so that the protective cap 6 is held in its position on the finished electric component 1 by the plastic 4.

This protective cap 6 is advantageously formed to be oil-tight. The partial over-molding of the protective cap 6 with plastic 4 prevents the penetration of oil at the edge of the protective cap 6, in the direction of the sensor 1.

Incorrect mounting of the component assembly 8 may be excluded by corresponding design of the components, for example by so-called poka-yoke design elements, and/or by test steps. For example, the design is such that the protective cap 6 cannot be pushed on and clipped and/or latched in the final position unless all components are in their respective correct positions.

As evident from the two exemplary embodiments depicted, a complexity of the electric components 1 produced according to the method can be expanded as desired. For example, several mounting supports 9 may be used, and/or the metal wires 10 may be arranged in several layers, and/or different metal wires 10 may be used, which are formed for example from different materials and/or have a different thicknesses and/or are galvanized or ungalvanized, and/or a multiplicity of electrical function elements 2, in particular sensors 2, may be used.

For this method, no costly punching and bending follow-on tools are required, and the tooling times required are shorter. For the metal wires 10, a simple low-cost wire material from a roll may be used, which is already pre-galvanized. Standard wire bending machines may be used.

Alternatively or additionally to the pre-bending of the metal wires 10 using such a bending machine, the mounting support 9 may be used as a bending aid which predefines the form to be achieved, wherein the metal wires 10 may then be bent manually for example using the mounting support 9 as a bending aid, i.e. as a template. In contrast to the method known from the prior art, no punching out is required, whereby associated tooling costs and process risks are avoided.

The mounting supports 9 are simple monolithic plastic parts which can be produced in a simple and economic fashion, in particular by means of the plastic injection molding process. In particular, no inlaying of parts in the plastic injection molding tool is required.

If the other electric components 1 mentioned above are produced using the method, these comprise at least the mounting support 9 and at least one electrically conductive metal wire 10. They may however also have one or more of the other components listed above, in particular one or more electrical function elements 2 which may be configured as sensors 2 or otherwise, and/or at least one sealing and/or holding element 7, and/or at least one protective cap 6.

The description of the invention is merely exemplary in nature and, thus, variations that do not depart from the gist of the invention are intended to be within the scope of the invention. Such variations are not to be regarded as a departure from the spirit and scope of the invention.

### LIST OF DESIGNATIONS

1 Component, sensor dome

2 Function element, sensor

3 Stamped grid

4 Plastic

5 Holding web

6 Protective cap

7 Sealing and/or holding element

8 Component assembly

9 Mounting support

10 Metal wire

11 Connecting contact

12 Protrusion

13 Groove

14 Fixing element

What is claimed is:

1. A method for producing an electric component comprising at least one component assembly, comprising:
providing a mounting support;
providing at least one electrically conductive metal wire;
arranging the at least one electrically conductive metal wire on or in the mounting support to form the at least one component assembly; and
over-molding at least one region of the at least one component assembly in a plastic molding process.

2. The method of claim 1, further comprising:
bending the at least one electrically conductive metal wire into a predefined form prior to arranging the at least one electrically conductive metal wire on or in the mounting support.

3. The method of claim 1, further comprising:
bending the at least one electrically conductive metal wire into a form predefined by the mounting support as the at least one electrically conductive metal wire is arranged on or in the mounting support.

4. The method of claim 1, further comprising providing the over-molding process to be a plastic injection molding process.

5. The method of claim 1, wherein the component assembly is formed comprising:
providing at least one electrical function element; and
arranging the at least one electrical function element on or in the mounting support such that the at least one electrical function element is connected to the at least one electrically conductive metal wire in an electrically conductive fashion.

6. The method of claim 5, further comprising providing the at least one electrical function element to be a sensor.

7. The method of claim 5, further comprising welding the at least one electrical function element to the mounting support

8. The method of claim 5, further comprising:
providing at least one sealing element; and
arranging the at least one sealing element on or in the mounting support.

9. The method of claim 8, further comprising:
providing the at least one sealing element to be made of plastic; and
forming the at least one sealing element during a plastic molding process.

10. The method of claim 5, further comprising:
providing at least one holding element; and
arranging the at least one holding element on or in the mounting support.

11. The method of claim 10, further comprising:
providing the at least one holding element to be made of plastic; and
forming the at least one holding element during a plastic molding process.

12. The method of claim 5, further comprising:
providing a protective cap; and
arranging the protective cap on the mounting support such that the protective cap is on or at least partially covers the at least one electrical function element.

13. The method of claim 12, further comprising:
providing the protective cap to be made of plastic; and
forming the protective cap during a plastic moulding process.

14. The method of claim 12, further comprising:
overmolding at least one region of the protective cap with plastic during a plastic molding process.

15. The method of claim 1, further comprising:
providing a plurality of plastic component assemblies, the at least one component assembly being one of the plurality of plastic component assemblies; and
over-molding at least one region of each of the plurality of component assemblies with plastic in a plastic molding process.

16. The method of claim 1, further comprising providing the electrical component to be a sensor dome.

17. The method of claim 1, further comprising providing the electrical component to be a plug.

18. An electric component, comprising:
at least one component assembly, the component assembly further comprising:
a mounting support; and
at least one electrically conductive metal wire which is arranged on or in the mounting support;
wherein the at least one component assembly is overmolded with a plastic at least in regions of the at least one component.

19. The electric component of claim 18, further comprising at least one electrical function element arranged on or in the mounting support and connected in electrically conductive fashion to the at least one electrically conductive metal wire.

20. The electric component of claim 19, wherein the at least one electrical function element is welded to the at least one electrically conductive metal wire.
